(19) United States
(12) Patent Application Publication
(10) Pub. No.: US 2005/0207102 A1
(43) Pub. Date: Sep. 22, 2005

(54) Protective cover for a computer

(75) Inventor: Christopher D. Russo, San Diego, CA (US)

Correspondence Address: FITCH EVEN TABIN & FLANNERY, 120 SOUTH LASALLE SUITE 1600, CHICAGO, IL, 60603, US

(73) Assignees: Sony Corporation, Tokyo (JP); Sony Electronics Inc., Park Ridge, NJ (US)

(21) Appl. No.: 10/804,791

(22) Filed: Mar. 19, 2004

(51) Int. Cl. G06F 1/16; H05K 5/00

(52) U.S. Cl. 361/683; 206/320

(57) ABSTRACT

A protective cover for an electronic device, such as a computer, is provided herein. In one implementation, the protective cover is for an electronic device having a display screen and user inputs, the cover comprising a cover portion; and a coupling portion adapted to removably couple the cover portion to the device, and adapted to allow the cover portion to be selectively positioned between a first and a second position. In the first position, the cover portion is positioned proximate to the user inputs and is sized to cover at least one user input and in the second position, the cover portion is positioned proximate to the display screen and is sized to cover at least a portion of the display screen. In preferred form, the cover portion is configured to limit an angle of view of the display screen through the cover portion when in the second position.

### BACKGROUND OF THE INVENTION

1. Field of the Invention

The present invention relates generally to computers, and more specifically to protective covers for computers displays and keyboards.

2. Discussion of the Related Art

The use of computing devices in close proximity to others raises privacy issues, especially when viewing sensitive information on the computer. For example, while a notebook style computer allows a user to be able to work while traveling on an airplane, train, bus, etc., an individual sitting next to the user can easily view the display screen. One solution has been the use of privacy film layers, typically made of a film material including microlouvers, adhered to the computer screen. This privacy film limits viewing of the display screen at an angle. Unfortunately, in the context of notebook computers, these privacy films are typically adhered or permanently affixed to the LCD screen of the monitor or the frame surrounding the screen, making removal difficult. Removal is desirable in instances where information on the screen is intended to be viewed by others, e.g., multiple viewers viewing a presentation.

Additionally, notebook computers have been increasingly used for viewing movies, such as DVDs, in order to pass time during a flight, train ride, etc. Particularly, with airplanes, space is limited and often food and/or beverages are served. Unfortunately, due to limited space, a viewer must stop viewing the movie or risk damaging the keyboard of the computer to food and/or beverage spills, since the keyboard is exposed.

### SUMMARY OF THE INVENTION

The invention provides a protective cover for an electronic device, such as a computer, which can be selectively positioned to protect a user input, such as at least a portion of a keyboard, and to protect at least a portion of a display screen.

In one embodiment, the invention can be characterized as a protective cover for an electronic device having a display screen and user inputs, the protective cover comprising a cover portion; and a coupling portion adapted to removably couple the cover portion to the electronic device, the coupling portion adapted to allow the cover portion to be selectively positioned between a first position and a second position. In the first position, the cover portion is positioned proximate to the user inputs and is sized to cover at least one user input and in the second position, the cover portion is positioned proximate to the display screen and is sized to cover at least a portion of the display screen.

In another embodiment, the invention can be characterized as a protective computer system comprising: a computer having a base including a keyboard and a lid including a display screen, the lid pivotally coupled to the base; a cover; and a coupling device adapted to removably couple the cover to the computer, the coupling device adapted to allow the cover portion to be selectively positioned between a first position and a second position. In the first position, the cover is positioned proximate to and over the keyboard and is sized to cover the keyboard; and in the second position, the cover is positioned proximate to the display screen such that the cover is between a viewer and the display screen and the cover is sized to cover the display screen, the cover adapted to limit an angle of view of the display screen through the cover.

In a further embodiment, the invention may be characterized as a method of protecting an electronic device having a display screen and user inputs, the method comprising the steps of: coupling a cover to a portion of the electronic device; positioning the cover to a first position, wherein in the first position, the cover is located proximate to the user inputs and is sized to cover at least one user input; repositioning the cover to a second position, wherein in the second position, the cover is relocated proximate to the display screen and is sized to cover at least a portion of the display screen.

### BRIEF DESCRIPTION OF THE DRAWINGS

The above and other aspects, features and advantages of the present invention will be more apparent from the following more particular description thereof, presented in conjunction with the following drawings.

FIGS. 1 and 3 are a perspective view and side view, respectively, of a protective cover for an electronic device, such as a computer as shown, illustrated in a first position covering at least a portion of a user input region of the computer in accordance with one embodiment of the invention.

FIGS. 2 and 4 are a perspective view and side view, respectively, of the protective cover of FIGS. 1 and 3 illustrated in a second position covering at least a portion of a display screen of the computer.

FIG. 5 is a perspective view of a protective cover for use with an electronic device which may be selectively positioned to cover either a portion of the user input region or a portion of the display screen of the device.

FIG. 6 is an enlarged perspective view of the protective cover of FIG. 5 illustrating a privacy film layer on one surface of the protective cover, in accordance with one embodiment of the invention.

FIG. 7 is a perspective view of one embodiment of a coupling piece used to couple the protective cover of several embodiments to the electronic device.

FIG. 8 is a perspective view of the protective cover of FIG. 5 including the coupling piece of FIG. 7.

FIG. 9 is a front view of a typical hinge configuration between a base portion and a display screen portion of a notebook or laptop style computer.

FIG. 10 is a perspective view of the coupling piece of FIG. 7 coupled to a hinge post of the computer of FIG. 9 and coupling the protective cover of several embodiments to the computer.

FIGS. 11 and 13 are a perspective view and side view, respectively, of an alternative coupling piece that couples the protective cover to the electronic device, e.g., a computer, the protective cover illustrated in the first position covering at least a portion of the user input region in accordance with another embodiment of the invention.

FIGS. 12 and 14 are a perspective view and side view, respectively, of the coupling piece of FIGS. 11 and 13 illustrated in the second position covering at least a portion of the display screen of the electronic device.

FIG. 15 is an enlarged perspective view of the coupling piece of FIGS. 11-14.

FIG. 16 is a top view of another embodiment of a protective cover including portions removed to expose components of the electronic device in accordance with another embodiment of the invention.

FIG. 17 is a top view of another embodiment of a protective cover including perforated portions that may be selectively removed to expose desired components of the electronic device in accordance with another embodiment of the invention.

FIG. 18 is a perspective view of another embodiment of a protective cover including a periphery edge or lip extending about the protective cover in accordance with another embodiment of the invention.

FIG. 19 is a perspective view of a variation of the protective cover of FIG. 18 in which portions removed to expose components through the protective cover also include a periphery edge or lip thereabout in accordance with another embodiment of the invention.

FIG. 20 is a perspective view of another embodiment of a protective cover illustrated in the first position in which channels are formed in a bottom surface of the protective cover to limit viewing at an angle.

FIG. 21 is a perspective view of the protective cover of FIG. 20 illustrated in the second position.

FIG. 22 is an enlarged perspective view of one channel of the cover of FIGS. 20-21 illustrating that the sides of the channels are coated with an opaque layer to limit the angle of view through the protective cover.

FIG. 23 is an illustration of how the channels of FIGS. 20-22 limit an angle of view through the protective cover.

FIG. 24 is a perspective view of a protective cover including a touch sensitive layer on an exposed surface of the cover when the cover is in the first position in accordance with another embodiment of the invention.

FIG. 25 is a cross sectional view of a portion of the protective cover including a touch sensitive layer.

FIG. 26 is a perspective view of a holding clip for holding the protective cover against a display screen when the display screen is in an upright orientation in accordance with another embodiment of the invention.

Corresponding reference characters indicate corresponding components throughout the several views of the drawings.

### DETAILED DESCRIPTION

The following description is not to be taken in a limiting sense, but is made merely for the purpose of describing the general principles of the preferred embodiments. The scope of the invention should be determined with reference to the claims.

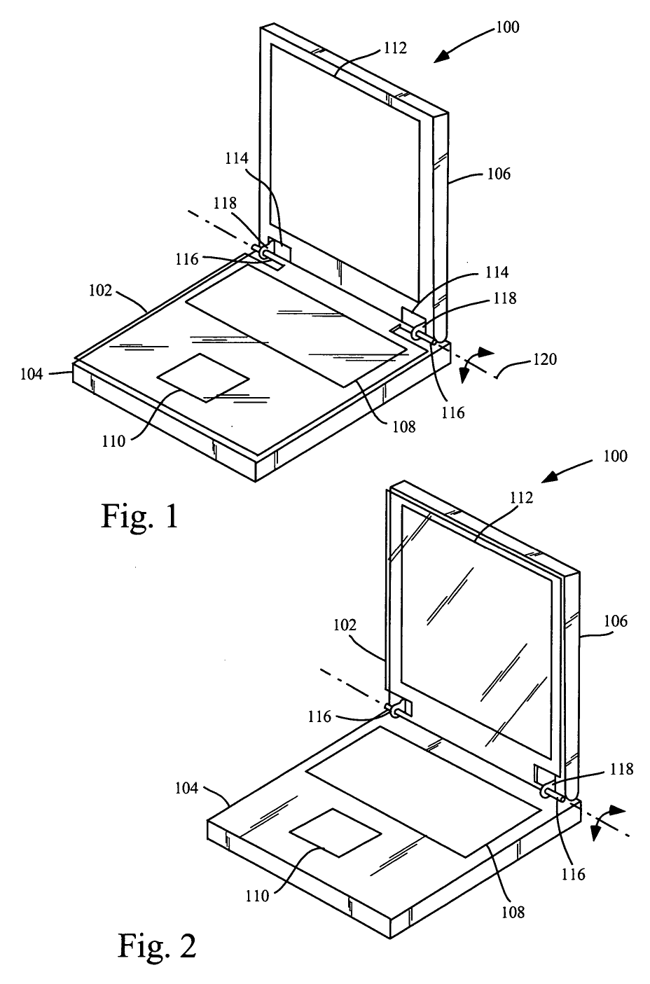

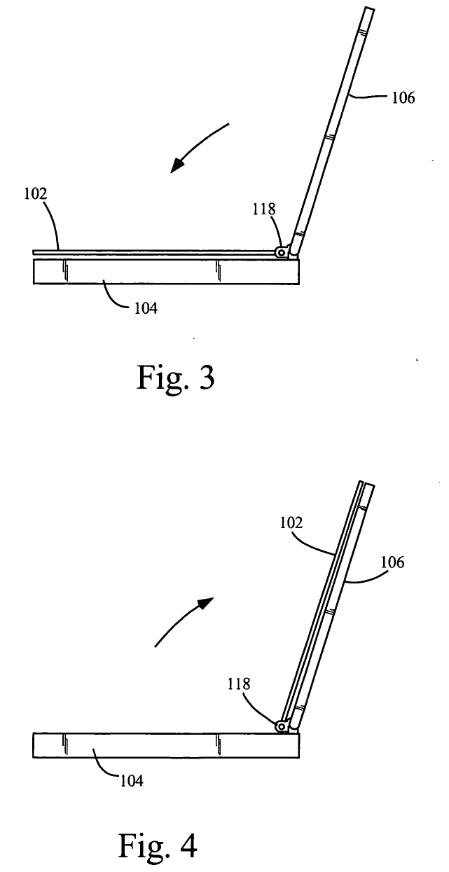

Referring first to FIGS. 1-4, perspective and side views are shown of a protective cover 102 (also referred to as a cover) for an electronic device, e.g., computer 100, in accordance with one embodiment of the invention. The cover 102 is selectably positioned between a first position and a second position. Illustrated in the first position in the views of FIGS. 1 and 3, the cover 102 covers at least a portion of a user input region of the computer 100. Illustrated in the second position in the views of FIGS. 2 and 4, the cover 102 covers at least a portion of a display screen of the computer 100.

Illustrated are the computer 100 and the cover 102. The computer 100 (referred to generically as an electronic device 100) includes a base portion 104 and a lid or display portion 106. The base portion 104 includes a keyboard 108 including a plurality of input keys and a touchpad 110, all of which may be generically referred to as a user input region having user inputs. The display portion 106 includes a display screen 112, such as a liquid crystal display (LCD) screen. The base portion 104 and the display portion 106 are coupled together by hinge portions 114. As illustrated, the computer 100 takes the form of a laptop or notebook style computer. It is noted that while in the preferred form, a computer is illustrated and described, the embodiments provided herein also apply to other types of electronic devices having user inputs and a display screen, for example, personal data assistants (PDAs), gaming machines, digital video disc (DVD) players, cellular telephones, etc.

According to several embodiments of the invention, the protective cover 102 removably attaches or couples to the computer 100 and serves to protect either a portion of the user inputs or a portion of the display screen 112. The cover 102 includes cover portion or body and a coupling portion (or coupling device) that is configured to allow for the removable attachment of the cover to the computer 100. In one embodiment, the coupling portion comprises a post 116 extending from one side of the cover 102. The post 116 is adapted to be inserted into a coupling piece (e.g., clip 118). The clip 118 is inserted over a hinge post of the hinge portion 114. The clip 118 can be easily clipped around and the hinge post and removed from the hinge post. Accordingly, the post 116 is rotatable within the piece 118 in order to position the cover 102 either in the first position or the second position. Since the post 116 is a part of the cover 102, the cover 102 pivots about axis 120. In preferred embodiments, the post 116 is friction fit within the coupling piece (e.g., clip 118) such that the cover 102 is held in position by friction. This is similar to how a hinge post fits within the hinge portion 114 of the base 104. Thus, advantageously, no matter what angle the display portion 106 is oriented at relative to the base 104, the cover 102 can be positioned proximate to the display portion 106 in order to cover the display screen 112 and be held in position against the display screen 112.

Advantageously, in the first position, the cover 102 is positioned proximate to and over the user inputs to cover and protect the user inputs. Since the cover is substantially rigid and generally non-deformable under normal force, objects may be placed on the cover 102 or the user may rest their hands on the cover and not depress any keys of the keyboard 108 or activate the touchpad 110. This is helpful where space for using the computer is limited, such as on an airplane or train. For example, a user may place a beverage or food item on the cover 102 while watching a movie on the computer 100. Again, the weight of the objects will not activate the user inputs. Thus, the cover will protect the user inputs against spills.

In the second position, the cover 102 is positioned proximate to the display screen 112 such that the cover is located between a viewer and the display screen. In preferred embodiments, in the second position, the cover 102 is configured to limit an angle of view of the display screen 102 through the cover 102. Generally, the cover 102 is made of a material that is substantially transparent such that one can see through the cover 102. In addition, in one embodiment, a layer of privacy film is located on one surface of the cover. The privacy film limits someone's ability to view the display screen from an angle to the side of the computer 100. Such privacy films are known in the art; however, have not been provided in an easily removable structure for a notebook style computer. In another embodiment, the cover 102 includes a structure formed within a surface of the cover 102 that limits the angle of view of the display screen 112. Such embodiments will be described in more detail below.

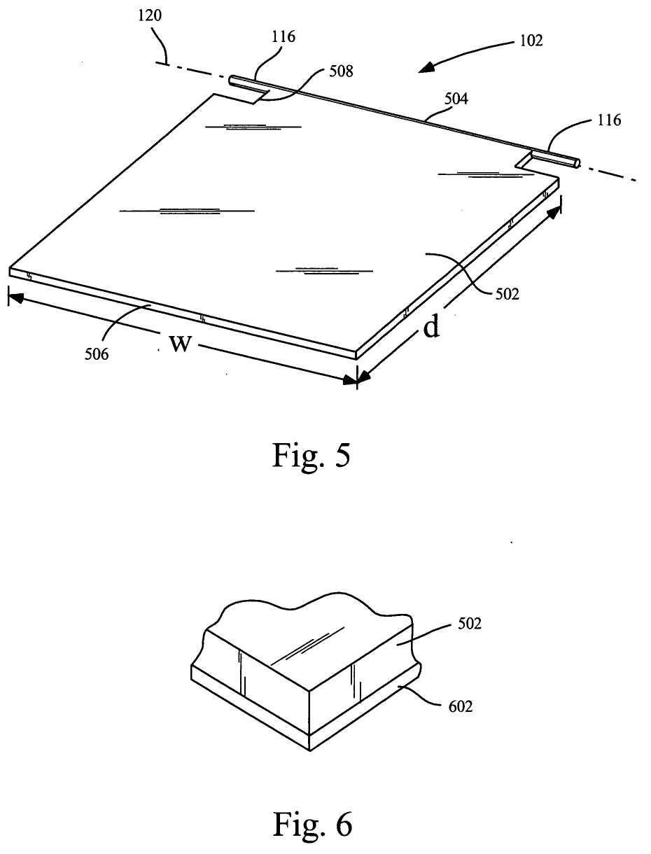

Referring next to FIG. 5, a perspective view is shown of the cover of FIGS. 1-4. The cover includes a body 502 (also referred to generically as a cover portion) having a pivot end 504 and a distal end 506. The body 502 also includes the posts 116 extending from the body 502 proximate to the pivot end 504. The posts may be generically referred to as a coupling portion that is adapted to removably couple the cover 102 to the computer.

In this embodiment, the body 502 is a substantially flat, rectangular plate that is generally sized to selectively cover at least a portion of the user inputs and at least a portion of the display screen of the computer. The body is substantially transparent, for example, the body comprises a clear plastic or acrylic material, e.g., LEXAN. Preferably, the body is substantially rigid and not deformable under normal use. The body is preferably thin, e.g., 0.5-5 mm thick. At its pivot end 504, the coupling portion is provided. In this embodiment, the posts 116 extend outwardly from a neck portion 508 of the body 502 at or near the pivot end 504. In this embodiment, the posts 116 are integral with the body 502; however, in other embodiments, a single post having a length of generally the width, w, of the body 102 is attached to the pivot end 504 of the body.

In this embodiment, the pivot end 504 of the body allows the body 502 to pivot about axis 120. The body extends a distance, d, to the distal end 506. The dimensions of the body 502 are such that the body 502 covers at least a portion of the user input region and at least a portion of the display screen 112.

Referring next to FIG. 6, an enlarged perspective view is shown of one embodiment of the cover 102 of FIG. 5 illustrating a privacy layer 602 on one surface of the body 504 of the cover 102. The privacy layer 602 is adhered or other located on the bottom surface of the body 502 (when the cover is in the first position). When positioned on the bottom surface, the privacy layer 602 is protected from tears or damage due to objects being placed directly on the body 502.

The privacy layer limits the angle of view therethrough. Such privacy films are well known in the art. For example, plastic light control films having microlouver structures such as manufactured by the 3M company are well known. It is understood that any type of filter, layer or material may be used to limit the angle of view therethrough. In preferred embodiments, the privacy layer 602 is adhered to the cover 102, as opposed to the display screen 112 or frame around the display screen forming the display portion 106. When the cover 102 is in the second position, i.e., the cover is positioned proximate to the display screen to be located in between the display screen and the user, the privacy layer limits the ability of someone sitting next to the computer user from being able to accurately view the information shown on the display screen.

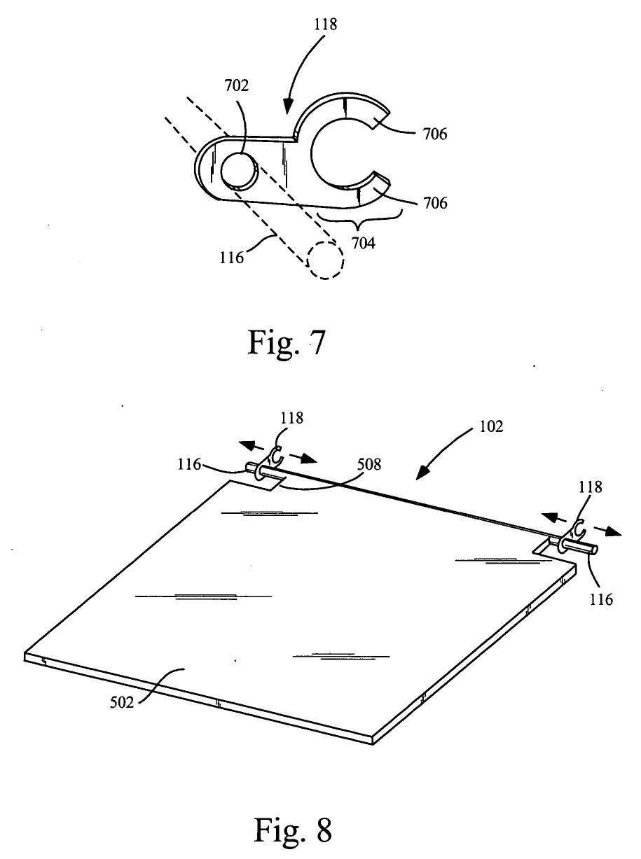

Referring next to FIG. 7, a perspective view is shown of one embodiment of a coupling piece 118 used to couple the cover to the electronic device. In this embodiment, the coupling piece 118 has a hole 702 formed at one end of the coupling piece. The hole 702 is adapted to receive the post 116 of the cover 102, for example, as shown FIG. 8. Preferably, the hole 702 is sized such that the post 116 friction fits within the hole in order to hold the post 116 in rotational position within the hole 702. The fit should also allow the post to be rotated within the hole 702 with slight to moderate force by the user. As shown in FIG. 8, the coupling pieces 118 may be moved (e.g., in the direction indicated by the arrows in FIG. 8) into the correct position on the post in order to account for computers having varying dimensions and locations for the hinges. It is noted that an end cap (not shown) may be positioned over the post 116 to prevent the coupling piece 118 from falling off of the post 116 when the cover is not in use.

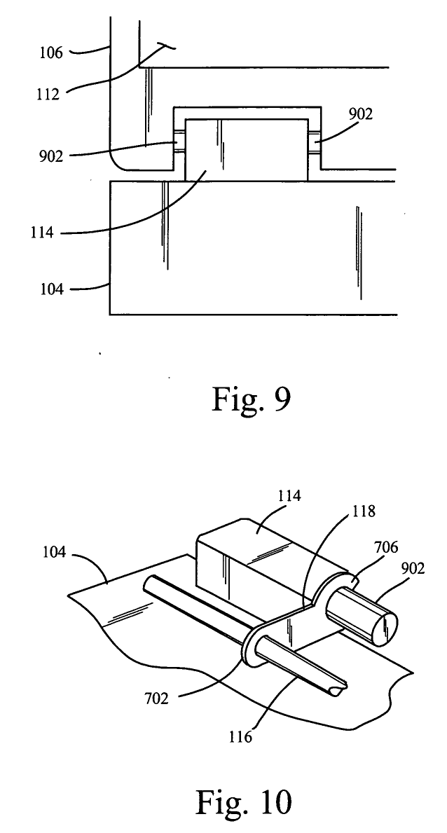

Generally, as shown in FIG. 9, the hinge portion 114 is rigidly coupled to the base 104 and a hinge post 902 extends through the hinge portion 114 to couple the display portion 106 to the base 104. The hinge post 902 rotates within the hinge portion 114 to allow the display portion 106 to pivot relative to the base 104.

At the end of the coupling piece 118 opposite the hole 702, the coupling piece 118 forms a C clip 704. The C-clip 704 has arms 706 adapted to clip or snap onto the hinge post 902. This is best illustrated in FIG. 10. Thus, the coupling piece 118 easily snaps over the hinge post 902 and also easily removes from the hinge post 902. This allows the cover 102 to be removably coupled to the computer so that the cover 102 can be put away when it is not desired for use. Additionally, since the post 116 is friction fit within the hole 702, the cover can be oriented to be against the display screen 112 or base 104 no matter what the angle between the display portion 106 and the base 104 and remain in that position.

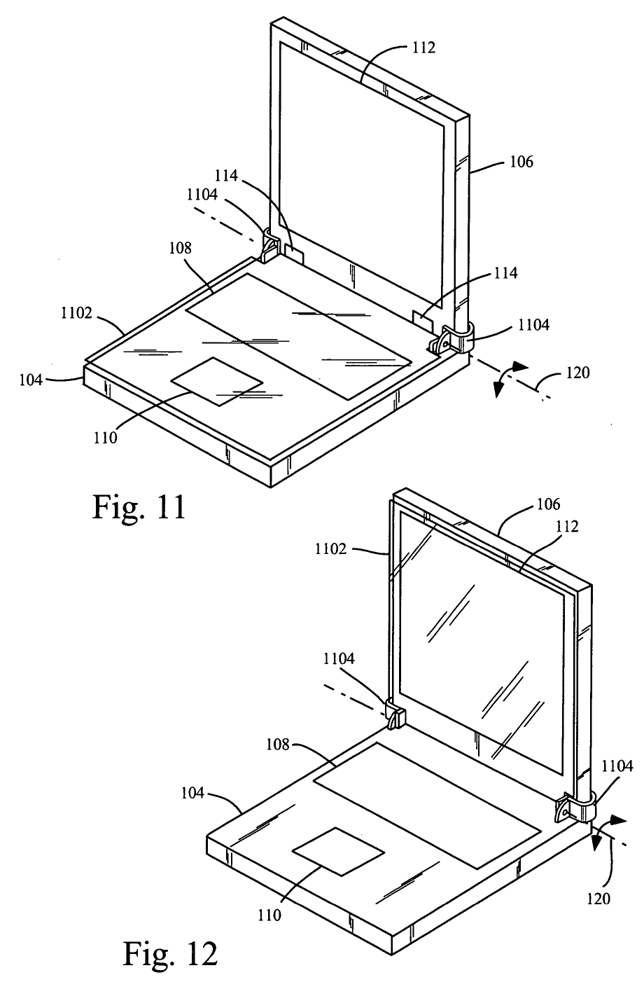

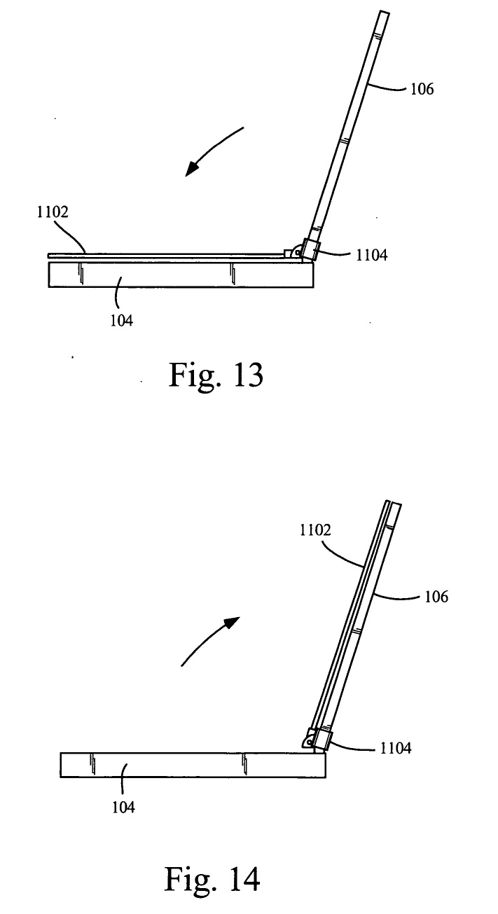

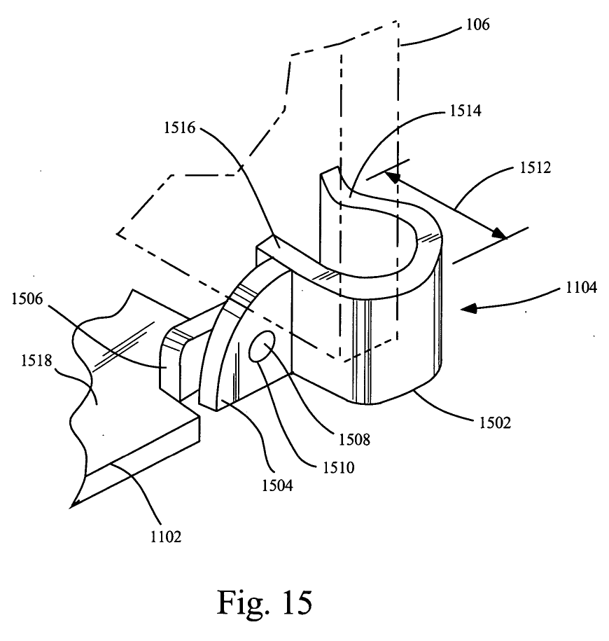

Referring next to FIGS. 11-14, perspective and side views are shown of a protective cover 1102 for an electronic device (e.g., the computer 100) having an alternative coupling portion to couple the cover to the electronic device in accordance with another embodiment of the invention. The cover 1102 is selectably positioned between the first position and the second position. Illustrated in the first position in the views of FIGS. 11 and 13, the cover 1102 covers at least a portion of the user input region of the computer 100. Illustrated in the second position in the views of FIGS. 12 and 14, the cover 1102 covers at least a portion of the display screen 112. While referring to FIGS. 11-14, concurrent reference will also be made to FIG. 15, which is an enlarged perspective view of the coupling piece of FIGS. 11-14.

In this embodiment, rather than coupling to the hinge 114 of the computer 100, the cover 1102 is clipped to the computer. The coupling piece 1104 is in the form of a clip 1502 that clips about the thickness of the display portion 106. A front side 1516 of the clip 1502 is generally flat and fits against a front surface of the display portion 106 (illustrated in dashed lines), while a back side 1514 of the clip 1502 fits against a back surface of the display portion 106. The back side 1514 is shaped to exert the majority of the clipping force on the back surface of the display portion 106, so as to not damage the display screen 112 in the event the front side 1516 sits against a portion of the display screen 112. The clip 1502 also extends out a distance 1512 in order to allow for display portions 106 that have varying widths, bezeling and cosmetics for different computers. Varying thickness of display portions 106 is accounted for in the flexibility and dimensions of the clip 1502 from the front side 1516 to the back side 1514 and the shaping of the back side. Typically, there is a greater difference in widths of display portions than the thickness of the display portions.

In this embodiment, a hinge piece 1504 is rigidly attached to the front side of the clip. The hinge piece 1504 has a hole 1510 formed therein. The hole 1510 is adapted to receive a post 1508 that is rotatable within the hole 1510. The post 1508 is rigidly attached to a coupling piece 1506 (generically referred to as a coupling portion of the cover) that is part of the body 1518 (cover portion) of the cover 1102 or is integral to the body 1518 depending on the embodiment. In preferred form, the post 1508 is friction fit within the hole 1510 such that the post 1508 (and thus, the coupling piece 1506 and the body 1518) will be held in angular position within the hole 1510. In alternative embodiments, the post 1508 loosely fits within the hole 1510.

In a variation, the post 1508 is rigidly attached to the hinge piece 1504 and fits within a hole (not shown) formed in the coupling piece 1506. It is also noted that although the post 1508 is illustrated as being flush with the outer surface of the hinge piece 1504, the post 1508 may extend a distance through the hole. Additionally, an end cap (not shown) may be positioned over the end of the post extending through the hole 1510 in order to prevent the post from falling out of the hinge portion 1504.

By using the coupling pieces 1506 and 1104, the cover 1102 can be removably coupled to the computer. That is, the cover 1102 can be non-permanently attached to the computer and removed when it is desired not to be used. Furthermore, the coupling pieces allow the cover to be selectively positioned between the first position (e.g., as seen in FIGS. 11 and 13) and the second position (e.g., as seen in FIGS. 12 and 14). Similar to that described above, the cover pivots about axis 120 (which in this case is in alignment with post 1508. The cover 1102 and its body serve the same functionality as described above in the embodiments of FIGS. 1-10. The coupling piece 1104 may be configured to be clipped to any portion of the computer although in preferred form, the piece 1104 clips to the display portion 106. For example, the piece 1104 may be coupled to the base 104 while taking care to avoid covering computer input/output devices and/or cooling vents.

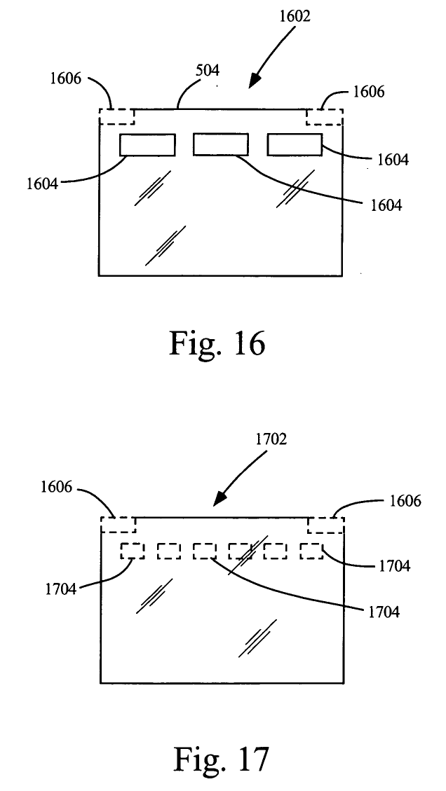

Referring next to FIG. 16, a top view is shown of another embodiment of a protective cover 1602 including portions or holes 1604 removed to expose components of the computer. In this embodiment, it is desired not to cover or protect all portions of the base. For example, particularly near the pivot end 504 of the cover 1602, the base 104 includes speakers or other controls, such as power button. For example, when watching a movie on the computer, it is preferred to not block the sound output from the speakers. The holes 1604 are formed in the cover 1602 and may be sized and located to correspond to the location of the speakers or other controls on the computer.

Referring next to FIG. 17, a top view is shown of another embodiment of a protective cover 1702 including perforated portions 1704 that may be selectively removed to expose desired components of the computer. Advantageously, depending on the location and size of components to be exposed while protecting the base, the user may “punch out” one or more perforated portions in order to create the appropriate holes, similar to those described in FIG. 16. It is noted that in FIGS. 16 and 17, a generic coupling portion 1606 is illustrated, which may take any of a variety of configurations, e.g., the coupling portions and pieces illustrated in FIGS. 1-15.

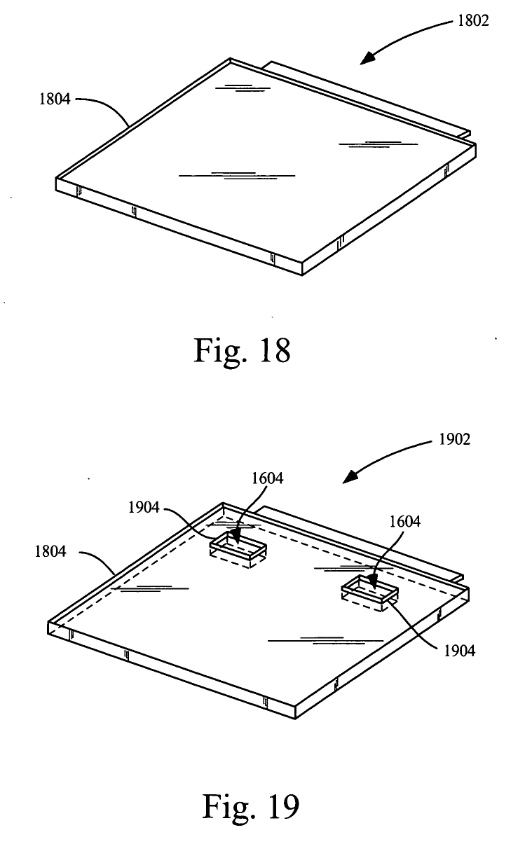

Referring next to FIG. 18, a perspective view is shown of another embodiment of a protective cover 1802 including a periphery edge 1804 or lip extending about the cover 1802 in accordance with another embodiment of the invention. The edge 1804 extends upward from the cover body when in the down position forming a recess in the central region of the cover. The edge serves to prevent or limit spilled substances from reaching the user inputs being protected. For example, if a user spills a drink or when condensation forms on the cover, the edge should prevent or at least limit the amount of liquid that reaches the base and/or the user inputs. By way of example, the edge is about 1-2 mm in height above the inner surface of the cover. It is also noted that the edge may extend over less than the entire periphery of the cover 1802.

A variation is shown in FIG. 19 in which portions (i.e., holes 1604) removed to expose components through the protective cover 1902 also include periphery edge 1904 or lip thereabout in accordance with another embodiment of the invention.

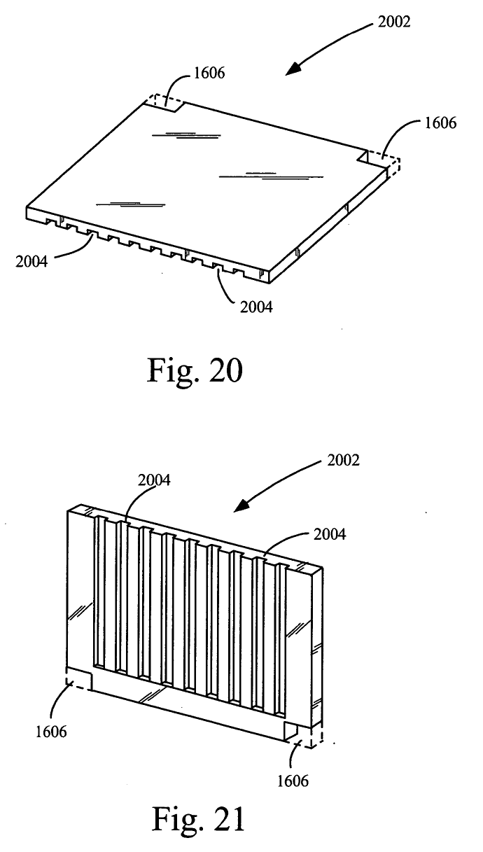

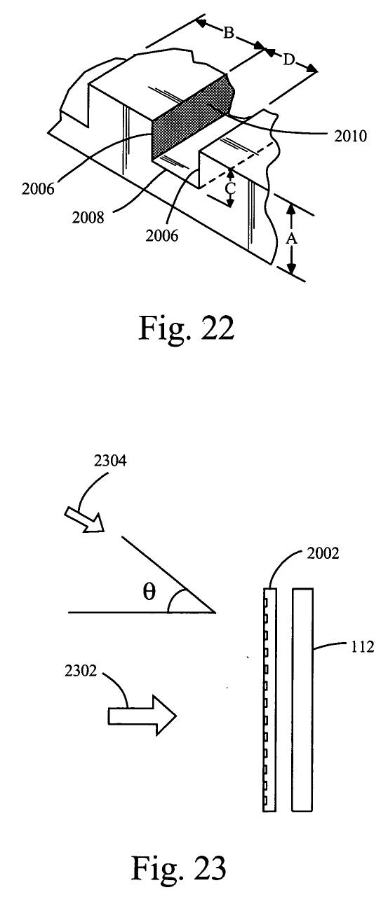

Referring next to FIGS. 20-21, perspective views are shown of another embodiment of a protective cover 2002 illustrated in the first position and the second position, respectively. Channels 2004 are formed in a bottom surface of the cover 2002 to provide for viewing privacy at an angle. Concurrent reference will also be made to FIG. 22, which is an enlarged view of a channel 2004. And FIG. 23 illustrates how the channels 2004 limit an angle of view through the cover 2002.

In this embodiment, channels are formed in a surface of the cover 2002, e.g., the bottom surface when the cover is in the first position and a surface facing away from the display screen when the cover 2002 is in the second position. Each channel 2004 has sidewalls 2006 and a bottom wall 2008 defining a length, width and depth. In the second position, the channels extend in a generally vertical direction on the surface of the cover. At least one sidewall 2006 includes a substantially opaque material 2010 coating the sidewall that substantially blocks viewing therethrough. Thus, the opaque material 2010 is configured to limit the angle of view of the display screen 112 through the cover 2002. The opaque material 2010 may be any suitable material, such as an adhesive strip, paint or other coating. Similar to that described above, the material of the cover 2002 is selected to be substantially transparent in order that a viewer can see through the cover.

The embodiments of FIGS. 20-23 are similar in functionality to the privacy film layer embodiments which are based on microlouvers within the plastic film. However, in FIGS. 20-23, the louver (i.e., channel) structure is on a much larger scale and is formed in the body of the cover 2002, not as a separate film. Such a cover may be easily fabricated by those of skill in the art, e.g., using an injection mold process.

As illustrated in FIG. 23, the view of the display screen is not limited for a viewer looking directly through the cover 2002 from the front of the display screen (shown as arrow 2302, the angle of view being normal to the plane of the display screen 112). This is because the opaque material 2010 is formed on surfaces parallel to the direction of view (arrow 2302). However, when the viewer is at an angle relative to the plane of the display screen (the direction of view shown by arrow 2304), the view of the display screen 112 is blocked in part by the opaque material 2010. This is because the direction of view 2304 is at an angle θ relative to the sidewalls 2006 having the opaque material 2010 formed thereon. That is as illustrated, the direction of view of arrow 2304 is at angle θ relative to the direction of view of angle 2302.

In several embodiments, depending on the material selected to form the cover 2002, the dimensions of the cover 2002 and channels 2004 should be considered to ensure that the cover has sufficient structural rigidity while limiting the angle of view. By way of example, as illustrated in FIG. 22, when the thickness A of the cover 2002 is a reference value of 2 mm, the width D of each channel 2004 should be no bigger than the channel spacing B (e.g., D≦B); the depth C of the channels should be less than half of the thickness A of the cover (e.g., C<0.5A); and the spacing B between channels should be no more than 3 times the thickness A (e.g., B≦3A). It should be understood that depending on the properties of the material selected and desired viewing angle limitations and rigidity, the dimensions may be varied.

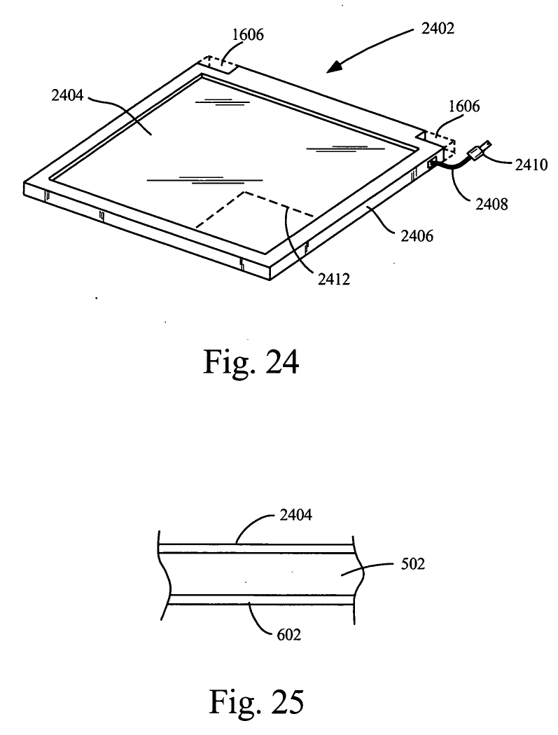

Referring next to FIG. 24, a perspective view is shown of a protective cover 2402 including a touch sensitive layer 2404 on an exposed surface of the cover 2402 when the cover is in a position covering a portion of the user input region in accordance with another embodiment of the invention. Concurrent reference will also be made to FIG. 25, which is a cross sectional view of a body portion of the cover 2002 including the touch sensitive layer 2404.

In this embodiment, the touch sensitive layer 2404 provides user input functionality while still generally protecting the normal user inputs on the base, such as the keyboard and the touchpad of the base 104. For example, the layer 2404 is a touch sensitive layer such as found on tablet personal computers (PCs) or portable data assistants (PDAs) or a similar material as found on the touchpads 110 of computers. Thus, responsive to pressure (from a user's finger or from a stylus), electrical signals are generated which are used by the computer to form a user input.

The cover 2402 includes a frame 2406, which may be made of a transparent or opaque material and includes electrical leads coupled to the layer 2404. However, if the frame is not transparent, the frame should be appropriately sized to avoid blocking the view of the peripheral edges of the display screen. An output line 2408 extends from the frame 2406 and terminates in an adapter 2410. In preferred embodiments, the adapter 2410 is a standard computer input and is plugged into an input port of the computer. For example, in one embodiment, the adapter is a universal serial bus (USB, e.g., USB 1.0 or 2.0) adapter that directly plugs into the corresponding USB port of the computer. With the proper driver software installed on the computer, the computer can recognize the input signals from the layer 2404 and operate accordingly.

The frame 2406 holds the body 502 of the cover 2402, which is substantially transparent, such as described above. The body 502 has the touch sensitive layer 2404 formed on one surface and the privacy film layer 602 formed on an opposite surface, as illustrated in FIG. 25.

It is noted that in some embodiments, the touch sensitive layer 2404 does not cover the entire body 502. For example, as illustrated by dashed lines 2412, the layer 2404 may cover a small portion of the surface of the body, for example, small corner portion. This would allow for a portion of the cover that a user could set objects on and another portion that serves as a user input.

The embodiments of FIGS. 24 and 25 could be useful in many situations. For example, the touch sensitive layer 2404 may be configured to operate movie playback controls while a user watches a movie on the computer and seeks to protect the keys or keyboard. Thus, if the user wishes to control playback, the user does not have to lift the cover 2402 to expose the controls on the base.

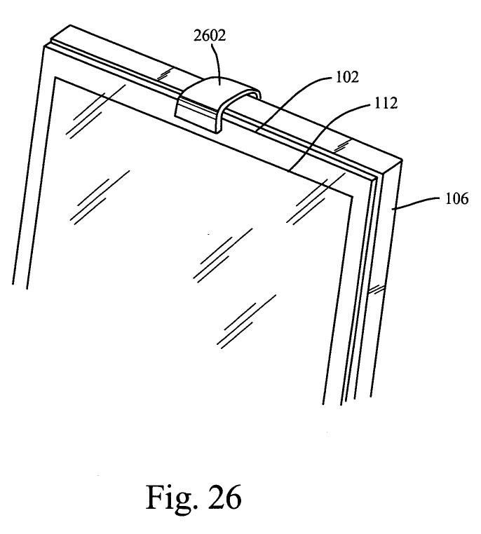

Referring next to FIG. 26, a perspective view is shown of a holding clip 2602 for removably holding the cover 102 against the display screen 112 when the display portion 106 is in an upright orientation in accordance with another embodiment of the invention. The holding clip 2602 is preferred in embodiments where the cover 102 is not held in angular position by a friction fit, such as described above. For example, the cover 102 freely rotates within the coupling piece that couples the cover to the computer. Thus, the clip 2602 is used to hold the cover against the display screen 112. Otherwise, the cover 102 may not stay in the upright orientation (e.g., the second position) due to gravity. It should be understood that other means for holding the covers described herein in an upright position may be used. For example, the coupling pieces may have a detent or other structure that the cover snaps into in the upright position. However, the described approaches are preferred since such detents may limit the angular position of the display portion 106 relative to the base 104 if the cover is to be positioned against the display screen 112.

While the invention herein disclosed has been described by means of specific embodiments and applications thereof, numerous modifications and variations could be made thereto by those skilled in the art without departing from the scope of the invention set forth in the claims. For example, although the present invention is described in the context electronic devices that are laptop or notebook style computers, it should be understood that invention may be easily adapted to fit other body styles of fixed and portable computers in which it is desired to selectively protect at least one user input and a display screen. Furthermore, the term electronic device as used herein also refers to any device having user input/s and a display screen, for example, computerized devices, personal computers, portable computers, personal data assistants (PDAs), gaming machines, digital video disc (DVD) players, cellular telephones, etc.

1. A protective cover for an electronic device having a display screen and user inputs, the protective cover comprising:
a cover portion; and
a coupling portion adapted to removably couple the cover portion to the electronic device, the coupling portion adapted to allow the cover portion to be selectively positioned between a first position and a second position;
wherein in the first position, the cover portion is positioned proximate to the user inputs and is sized to cover at least one user input;
wherein in the second position, the cover portion is positioned proximate to the display screen and is sized to cover at least a portion of the display screen.

2. The cover of claim 1 wherein, in the second position, the cover portion is configured to limit an angle of view of the display screen through the cover portion.

3. The cover of claim 2 wherein the cover portion comprises:
a transparent plate; and
a layer covering one surface of the transparent plate, the layer comprising a material configured to limit the angle of view of the display screen through the cover portion when the cover portion is in the second position.

4. The cover of claim 2 wherein the cover portion includes channels formed in one surface, the channels each having sidewalls and a bottom wall defining a length, width and depth of the channel;
a substantially opaque material coating at least one sidewall of the channels;
the substantially opaque material configured to limit the angle of view of the display screen through the cover portion.

5. The cover of claim 1 wherein the cover portion is substantially rigid.

6. The cover of claim 1 wherein the cover portion includes at least one hole.

7. The cover of claim 1 wherein the cover portion includes an edge extending about at least a portion of a periphery of one surface, the edge extending substantially upward when the cover portion is located in the first position.

8. The cover of claim 1 wherein the coupling portion comprises:
a post coupled to the cover portion;
a piece adapted to receive a portion of the post such that the post is rotatable within the piece, the piece further adapted to removably and rigidly couple to the electronic device.

9. The cover of claim 8 wherein the piece removably couples to a hinge of the electronic device, the electronic device having a base portion and a display portion hinged together.

10. The cover of claim 8 wherein the piece comprises a clip that can be removably attached to a portion of the electronic device.

11. The cover of claim 8 wherein the piece and the post are configured such that the post is friction fit within the piece, such that the cover portion is held in position by the friction fit.

12. The cover of claim 1 further comprising a clip removably coupling the cover portion proximate to the display screen when the cover portion is in the second position.

13. The cover of claim 1 further comprising:
a touch sensitive layer positioned on at least a portion of an exposed surface of the cover portion in the first position, the touch sensitive portion serving as a user input.

14. The cover of claim 1 wherein in the first position, the cover portion is sized to cover the user inputs and in the second position, the cover portion is sized to cover the display screen.

15. A protective computer system comprising:
a computer having a base including a keyboard and a lid including a display screen, the lid pivotally coupled to the base;
a cover; and
a coupling device adapted to removably couple the cover to the computer, the coupling device adapted to allow the cover portion to be selectively positioned between a first position and a second position;
wherein in the first position, the cover is positioned proximate to and over the keyboard and is sized to cover the keyboard; and
wherein in the second position, the cover is positioned proximate to the display screen such that the cover is between a viewer and the display screen and the cover is sized to cover the display screen, the cover adapted to limit an angle of view of the display screen through the cover.

16. The cover of claim 15 wherein the cover comprises:
a transparent plate; and
a layer covering one surface of the transparent plate, the layer comprising a material configured to limit the angle of view of the display screen through the cover when the cover is in the second position.

17. The cover of claim 15 wherein the cover includes channels formed in one surface, the channels each having sidewalls and a bottom wall defining a length, width and depth of the channel;
a substantially opaque material coating at least one sidewall of the channels;
the substantially opaque material configured to limit the angle of view of the display screen through the cover.

18. The cover of claim 15 wherein the cover is substantially rigid.

19. The cover of claim 15 wherein the cover includes at least one hole.

20. The cover of claim 15 wherein the cover includes an edge extending about at least a portion of a periphery of one surface, the edge extending substantially upward when the cover is located in the first position.

21. The cover of claim 15 wherein the coupling device comprises:
a post coupled to the cover;
a piece adapted to receive a portion of the post such that the post is rotatable within the piece, the piece further adapted to removably and rigidly couple to the computer.

22. The cover of claim 21 wherein the piece removably couples to a hinge of the computer.

23. The cover of claim 21 wherein the piece comprises a clip that can be removably attached to a portion of the computer.

24. The cover of claim 21 wherein the piece and the post are configured such that the post is friction fit within the piece, such that the cover is held in position by the friction fit.

25. The cover of claim 15 further comprising a clip removably coupling the cover proximate to the display screen when the cover is in the second position.

26. The cover of claim 15 further comprising:
a touch sensitive layer positioned on at least a portion of an exposed surface of the cover in the first position, the touch sensitive portion serving as a user input.

27. A method of protecting an electronic device having a display screen and user inputs, the method comprising:
coupling a cover to a portion of the electronic device;
positioning the cover to a first position, wherein in the first position, the cover is located proximate to the user inputs and is sized to cover at least one user input;
repositioning the cover to a second position, wherein in the second position, the cover is relocated proximate to the display screen and is sized to cover at least a portion of the display screen.

28. The method of claim 27 further comprising:
limiting an angle of view of the display screen through the cover when the cover is in the second position.

29. The method of claim 27 further comprising:
placing, after the positioning step, an object on the cover without activating the at least one user input.

30. The method of claim 27 wherein the repositioning step comprises:
pivoting the cover about an axis to relocate the cover to the second position.

31. The method of claim 27 wherein the coupling step comprises:
clipping the cover to the portion of the electronic device.

32. The method of claim 27 further comprising:
removing the cover from the electronic device.
